(19) United States
(12) Patent Application Publication
(10) Pub. No.: US 2025/0072138 A1
(43) Pub. Date: Feb. 27, 2025

(54) IMAGE SENSOR

(71) Applicant: Commissariat à I'Énergie Atomique et aux Énergies Alternatives, Paris (FR)

(72) Inventors: Gaelle Palmigiani, Grenoble (FR); Nicolas Billon-Pierron, Grenoble (FR); François Ayel, Grenoble (FR)

(73) Assignee: Commissariat à I'Énergie Atomique et aux Énergies Alternatives, Paris (FR)

(21) Appl. No.: 18/800,342

(22) Filed: Aug. 12, 2024

(30) Foreign Application Priority Data
Aug. 21, 2023 (FR) 2308824

(51) Int. Cl. H01L 27/146

(52) U.S. Cl. CPC H01L 27/1461

(57) ABSTRACT

An image sensor including a plurality of pixels, each pixel including a non-pinned photodiode connected, by a metal connecting element, to a pinned region formed in a first semiconductor substrate.

### CROSS REFERENCE TO RELATED APPLICATIONS

This application claims priority to French application number 2308824, filed Aug. 21, 2023. The contents of which is incorporated by reference in its entirety.

### TECHNICAL FIELD

The present description relates generally to the field of electronic devices, more particularly to image sensors and image sensor pixels.

### BACKGROUND ART

Among the pixels used in existing image sensors, pixels comprising a non-pinned photodiode, combined with a so called “3T” readout circuit including three MOS (Metal Oxide Semiconductor) transistors, have been proposed. These circuits typically comprise a MOS transistor for resetting a photosensitive node, a MOS follower transistor, and a MOS transistor for selecting the pixel. The photosensitive node of the pixel, which corresponds to the cathode of the photodiode, is connected to a conduction electrode of the reset MOS transistor and to a gate electrode of the follower MOS transistor, while the conduction electrodes of the selection MOS transistor are connected to a conduction electrode of the follower MOS transistor and to a column conductive track of the image sensor, respectively. The voltage of the photosensitive node is first initialized in a reset phase. During a subsequent exposure phase, the photosensitive node undergoes a voltage drift caused by a current, produced by the photodiode, proportional to an incident luminous flow. At the end of the exposure phase, the voltage present at the photosensitive node, from which the reset voltage is subtracted and which thus corresponds substantially to the light signal integrated by the pixel, is copied back to the image sensor column (to within a gate-source voltage) in order to be subsequently read and processed at the foot of the column. One drawback of pixels of this type is that the value of the reset voltage is parasitized by sampling noise, or kTC noise. Since the parasitic voltage is not correlated with the voltage present at the photosensitive node at the end of the exposure phase, the value of the signal read by the readout circuit is polluted by kTC noise. This adversely affects the quality of the images acquired by the sensor.

Furthermore, photosites of depth image sensor comprising a non-pinned photodiode combined with a 3T-type readout circuit have been proposed for indirect Time-of-Flight (iToF) distance measurement. These depth photosites implement a sampling function allowing the distance between the sensor and objects in the scene to be imaged to be determined. Using a non-pinned photodiode in this type of application means sampling a current produced by the photodiode. This has numerous drawbacks, such as parasitic coupling, loss of operating point of the structure (e.g. loss of a photodiode bias voltage, loss of signal, etc.), degraded frequency response, noisy sampled value, etc. This distorts the depth measurements of the image sensor, and lead to results that are difficult to use.

In an attempt to overcome these various drawbacks, image sensor pixels comprising a pinned photodiode (PPD), combined with a so called-4T readout circuit including four MOS transistors, have been proposed. The pinned photodiode of these pixels typically comprises an N-type doped semiconductor region formed in a P-type doped semiconductor substrate, and separated from a top face of the substrate by a thin, highly doped P-type semiconductor layer (P⁺ layer). Furthermore, in these pixels, in addition to the MOS transistors described above for the 3T readout circuit, the readout circuit includes an additional MOS charge transfer transistor. In this case, the readout circuit of the pixel includes an intermediate memory node, or sense node, interposed between the photosensitive node and the gate electrode of the follower MOS transistor. The photosensitive node is thus dissociated from the sense node, enabling the sense node to be used as a charge storage node. At the end of an exposure phase, during which the photosensitive node integrates and converts the incident luminous flow into charge packets, the sense node is first reset to a reset voltage, which is read and stored at the foot of the column. A subsequent transfer phase then allows the charge packets from the photosensitive node to be transferred to the sense node. The resulting signal voltage is then in turn read and stored at the foot of the column. Reset and signal voltages are therefore correlated. By subtracting the reset voltage from the signal voltage, kTC noise is eliminated, resulting in a noise-free image.

However, it may prove difficult, or even impossible, to implement a pinned photodiode associated with a 4T readout circuit, for example due to constraints linked to the materials or manufacturing methods used to form the photodiode.

### SUMMARY OF INVENTION

There is a need to overcome some or all of the drawbacks of existing image sensor pixels or photosites. In particular, there is a need to overcome drawbacks associated with the use of image sensor pixels comprising a non-pinned photosensitive diode, or photodiode.

For this purpose, one embodiment provides an image sensor comprising a plurality of pixels, each pixel including a non-pinned photodiode connected, by a metallic connection element, to a pinned area formed in a first semiconductor substrate.

According to one embodiment, the non-pinned photodiode comprises a P-type doped anode semiconductor region and an N-type doped cathode semiconductor region.

According to one embodiment, the anode and cathode semiconductor regions of the non-pinned photodiode are joined.

According to one embodiment, the non-pinned photodiode is formed on a second semiconductor substrate different from the first substrate.

According to one embodiment, the non-pinned photodiode is hybridized to the first substrate, the first substrate being made of silicon.

According to one embodiment, the metallic connection element comprises conductive tracks, conductive vias and/or contact pick-up elements formed in first and second interconnection stacks located on the first and second substrates, respectively.

According to one embodiment, the pinned area comprises a first N-type doped semiconductor region formed in the first substrate, the first substrate being P-type doped.

According to one embodiment, a second P-type doped semiconductor region formed in the first substrate is interposed between a top face of the first substrate and the first semiconductor region.

According to one embodiment, the second semiconductor region has a higher doping level than the first substrate.

According to one embodiment, the metal connection element is in contact with a third N-type doped semiconductor region extending vertically through the thickness of the first substrate from its top face.

According to one embodiment, the first semiconductor region penetrates into the third semiconductor region.

According to one embodiment, each pixel further includes a transistor connected between the metal connection element and the pinned area.

According to one embodiment, the pixel further comprises:
at least one first photosensitive area formed in the first substrate and adapted to collect light in a first range of wavelengths;
a fourth semiconductor region formed in the first substrate in line with said at least one photosensitive area, in which the pinned area is formed;
at least one charge-collecting area disposed on the side of the second substrate opposite said at least one first photosensitive area;
at least one transfer region extending from said at least one first photosensitive area to said at least one charge-collecting area; and
at least one transfer gate extending vertically between said at least one transfer region and the fourth semiconductor region, and laterally bordering said at least one transfer region.

According to one embodiment, the non-pinned photodiode is adapted to capture light in a second wavelength range, different from the first wavelength range.

According to one embodiment, the pixel further includes at least one another transfer gate extending laterally on said side of the first substrate opposite said at least one first photosensitive area and at least one another charge collection area.

According to one embodiment, the pinned area is not intended to be subjected to incident light radiation.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 illustrates, schematically and partly, an example pixel of image sensor according to one embodiment;

FIG. 2 is a partial schematic side and sectional view of an example of the pinned area of the pixel shown in FIG. 1 according to one embodiment;

FIG. 3 is a schematic, partial side and sectional view of an example image sensor according to one embodiment;

FIG. 4A, FIG. 4B, FIG. 4C, and FIG. 4D are graphs illustrating operating steps of the pixel shown in FIG. 1 according to one embodiment;

FIG. 5 is a graph illustrating an alternative operation of the pixel shown in FIG. 1;

FIG. 6A and FIG. 6B are schematic, partial top and sectional views along plane BB shown in FIG. 6A, respectively, of an image sensor pixel according to one embodiment;

FIG. 7 illustrates, schematically and partly, an example image sensor pixel according to one embodiment;

FIG. 8 is a partial schematic side and sectional view of an example pinned area of the pixel shown in FIG. 7 according to one embodiment; and

FIG. 9 is a graph illustrating a step of operation of the pixel shown in FIG. 7 according to one embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the readout circuits, or column decoders, the control circuits, or line decoders, and the applications in which image sensors can be provided have not been described in detail, as the embodiments and variants described are compatible with the readout circuits and control circuits of conventional image sensors, as well as with conventional applications involving image sensors.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

In the following description, “visible light” refers to electromagnetic radiation with a wavelength between 380 nm and 780 nm, and “infrared radiation” refers to electromagnetic radiation with a wavelength between 780 nm and 15 μm. Further, “near infrared radiation” refers more specifically to electromagnetic radiation with a wavelength between 780 nm and 1.7 μm.

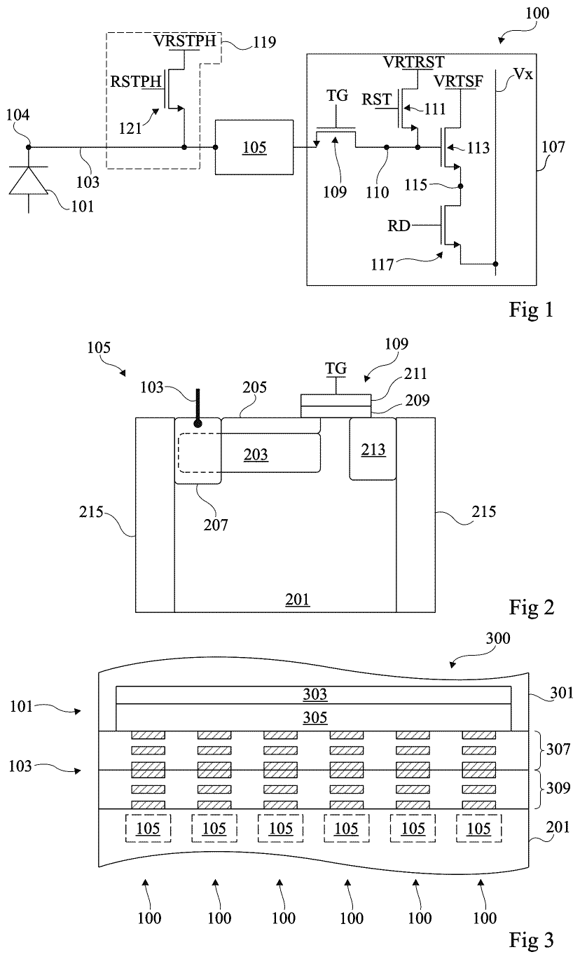

FIG. 1 illustrates, schematically and partly, an example pixel 100 of an image sensor according to one embodiment.

In the example shown, pixel 100 comprises a photosensitive diode or photodiode 101. The photodiode 101 of pixel 100 is non-pinned and comprises, for example, a P-type doped anode semiconductor region connected to an anode electrode, and an N-type doped cathode semiconductor region connected to a cathode electrode. By way of example, the anode and cathode semiconductor regions of photodiode 101 are joined, with the anode region in contact with the cathode region, and form a PN junction. Alternatively, the anode and cathode semiconductor regions of photodiode 101 can be separated from each other, photodiode 101 then comprising at least one intermediate layer interposed between the anode and cathode regions, for example an intermediate layer in which multiple quantum dots are formed.

According to one embodiment, the non-pinned photodiode 101 of pixel 100 is connected, by a metallic connection element 103, to a pinned area 105. More specifically, in the example shown, a node 104 corresponding, for example, to the cathode electrode of the photodiode 101 is connected, by the metal connection element 103, to the pinned area 105. The pinned area 105 is offset, for example.

In the example shown, the pinned area 105 is further connected to a readout circuit 107. In the example shown, the readout circuit 107 is of the “4T” type and comprises four MOS transistors:
a charge transfer MOS transistor 109, one conduction terminal of which, e.g. the source, is connected to the pinned area 105, another conduction terminal of which, e.g. the drain, is connected to a sense node 110, and a control terminal, or gate, of which is connected to a node for applying a control voltage TG;
a reset MOS transistor 111, one conduction terminal of which, e.g. the source, is connected to the sense node 110, another terminal of which, e.g. the drain, is connected to a node for applying a reset voltage VRTRST, and a control terminal, or gate, of which is connected to a node for applying a control voltage RST;
a follower MOS transistor 113, one conduction terminal of which, e.g. the source, is connected to an internal node 115 of the readout circuit 107, another conduction terminal of which, e.g. the drain, is connected to a node for applying a voltage VRSTF, and a control terminal, or gate, of which is connected to the sense node 110; and
a selection MOS transistor 117, one conduction terminal of which, e.g. the source, is connected to a column conductive track Vx of the image sensor, another conduction terminal of which, e.g. the drain, is connected to the internal node 115, and a control terminal, or gate, of which is connected to a node for applying a control voltage RD.

Optionally, the pixel 100 can further include a circuit 119 comprising a reset MOS transistor 121 connected to the metal connection element 103, between the photodiode 101 and the pinned area 105. In this case, the MOS transistor 121 comprises a conduction terminal, e.g. the source, connected to the metal connection element 103, another conduction terminal, e.g. the drain, connected to a node for applying a reset voltage VRSTPH, and a control terminal, or gate, connected to a node for applying a control voltage RSTPH.

Voltages TG, VRTRST, RST, VRSTF, RD, VRSTPH, and RSTPH, for example, are referenced to a reference potential (not shown in FIG. 1), such as ground.

By way of example, the photodiode 101 of pixel 100 is intended to capture visible light. Alternatively, photodiode 101 may be intended to capture infrared radiation, such as near-infrared radiation. The pixel 100 may, in this case, be a depth photosite or pixel the photodiode 101 of which is connected to one or more readout circuits of the type of circuit 107 previously described.

The operation of the pixel 100, and in particular the of readout circuit 107, will be explained in greater detail below.

FIG. 2 is a schematic, partial side and sectional view of an example pinned area 105 of the pixel 100 shown in FIG. 1, according to one embodiment.

In the example shown, pinned area 105 is formed in a semiconductor substrate 201, for example a wafer or piece of wafer made of a semiconductor material, such as silicon. In this example, the semiconductor substrate 201 is P-type doped. The semiconductor substrate 201 includes an N-type doped semiconductor region 203. In the orientation shown in FIG. 2, region 203 extends laterally below the top surface of substrate 201. By way of example, region 203 has a doping level of between 1.10¹⁰ and 1.10¹⁸ at./cm³.

In the example shown, a P-type doped semiconductor region 205 is interposed between region 203 and the top surface of substrate 201. The region 205 allows, for example, the surface of the substrate 201 to be passivated. For example, region 205 has a higher doping level than substrate 201.

Furthermore, in the example shown, the metallic connection element 103 is in contact with a highly N-type doped (N⁺ doping) semiconductor region 207 extending vertically through the thickness of the substrate 201 from its top face. In the example shown, region 203 penetrates into region 207. Region 207, for example, has a higher doping level than region 203. The doping level of region 207 is chosen, for example, so as to enable optimum electrical connection with the metallic connection element 103. By way of example, region 207 has a doping level of between 1.10¹⁷ and 5.10²⁰ at./cm³.

In the example shown, the MOS transfer transistor 109 comprises a gate region including an electrically insulating layer 209 interposed between an electrically conductive layer 211, acting for example as the gate electrode of the MOS transistor 109, and the top face of the substrate 201. In the illustrated example, the gate region extends laterally over regions 203 and 205, with region 203 forming, for example, a source region of MOS transistor 109, and over another, highly N-type doped semiconductor region 213 forming, for example, a drain region of MOS transistor 109. The region 213 has, for example, a doping level substantially equal to that of the region 207. Region 213 is separated laterally from regions 203 and 205 by a part of substrate 201.

In the example shown, a peripheral isolation trench 215, for example a Capacitive Deep Trench Isolation (CDTI) trench, is formed in the semiconductor substrate 201. When viewed from above, the peripheral isolation trench has, for example, an annular shape surrounding regions 203, 205, 207, and 213.

In the example shown in FIG. 2, the pinned area 105 corresponds, for example, to the N-type doped region 203 interposed vertically between the highly P-type doped region 205 and the P-type doped substrate 201. Pinned area 105 has a pinch-off voltage Vp depending in particular on the doping level, geometry and environment of semiconductor region 203.

The pinned area 105 is for example formed in a part of the image sensor not exposed to the incident radiation intended to be picked up by the photodiode 101 of the pixel 100. For example, the substrate 201 is devoid of photosensitive areas, and the pinned area 105 is not intended to be subjected to incident light radiation.

FIG. 3 is a schematic, partial side and sectional view of an example image sensor 300 according to one embodiment.

In the example shown, the image sensor 300 comprises a plurality of pixels 100. The photodiodes 101 of the pixels 100 are for example formed on a substrate 301, such as a wafer or a piece of wafer made of a semiconductor material, for example other than silicon. In the illustrated example, the photodiodes 101 comprise two photosensitive layers 303 and 305, for example joined together, forming a PN junction. By way of example, layers 303 and 305 are made of materials sensitive to near-infrared radiation. Layers 303 and 305 are hybridized to substrate 201, for example. Layers 303 and 305 correspond, for example, to the anode and cathode semiconductor regions of photodiode 101, respectively.

The substrate 301 comprises, on the side of the back face thereof, in the orientation shown in FIG. 3, an interconnection stack 307 consisting of alternating dielectric and conductive layers. Conductive tracks are formed in the conductive layers, or metallization levels, for example, whereby conductive tracks belonging to different layers can be connected to one another by conductive vias.

In the example shown, the substrate 201 in which the pinned areas 105 of the pixels 100 are formed is overlaid by an interconnection stack 309, for example analogous to the interconnection stack 307. In the orientation shown in FIG. 3, the interconnection stack 309 is in contact, via its bottom face, with the bottom face of interconnection stack 307. By way of example, interconnection stacks 307 and 309 are brought into contact and mechanically attached to each other by molecular bonding, for example by hybrid molecular bonding. In this case, contact pick-up elements flush with the top face of interconnection stack 309 are, for example, brought into contact with contact pick-up elements flush with the bottom face, in the orientation shown in FIG. 3, of interconnection stack 307.

In the example shown in FIG. 3, the metal connection element 103 of each pixel 100 comprises, for example, metal conductive tracks, conductive vias and/or contact pick-up elements formed in the interconnection stacks 307 and 309. Although the metallic connection elements 103 have not been detailed in FIG. 3 so as not to overload the drawing, their implementation is within the capabilities of those skilled in the art based on the indications of the present description.

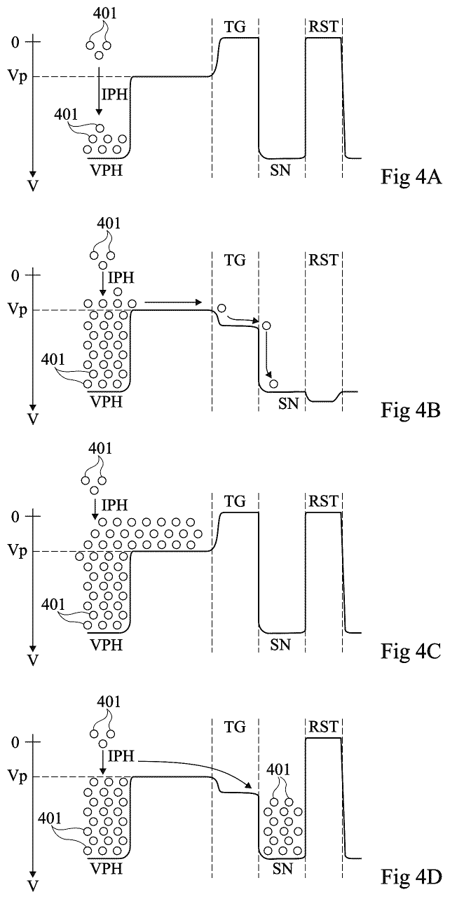

FIG. 4A, FIG. 4B, FIG. 4C, and FIG. 4D are graphs illustrating operating steps of the pixel 100 shown in FIG. 1 according to one embodiment. More specifically, FIGS. 4A to 4D illustrate variations in a voltage V at different points on the pixel 100. In particular, FIGS. 4A to 4D illustrate variations in:
a control voltage VPH applied to node 104;
the voltage TG applied to the gate of charge transfer MOS transistor 109;
a voltage SN applied to sense node 110; and
the control voltage RST applied to the gate of reset MOS transistor 111.

More specifically, FIG. 4A illustrates a preliminary step in which photogenerated charges 401, here electrons, are accumulated at node 104 under the effect of a current IPH produced by photodiode 101 until the voltage VPH present at node 104 becomes substantially equal to the pinch-off voltage Vp of pinned area 105. During this step, the charges accumulated at node 104 fill the potential well formed by the metal connection element 103. The charges accumulated at node 104 during this step will not, however, be transferred to the sense node 110 during subsequent steps.

To speed up this process, the optional reset MOS transistor 121 can be used to initialize the voltage present at node 104 to a value close to that of the pinch-off voltage Vp. The reset voltage VRSTPH may, for example, be slightly higher than the pinch-off voltage Vp. Alternatively, the reset voltage VRSTPH may be lower than the pinch-off voltage Vp, with the excess charges accumulated at node 104 subsequently discharged in a subsequent reset step.

Once the potential well formed by the metallic connection element 103 is filled, i.e. once the voltage present at node 104 is substantially equal to the pinch-off voltage Vp, photogenerated charges begin to accumulate in the pinned area 105.

More specifically, FIG. 4B illustrates a subsequent step for resetting the pinned area 105 and the sense node 110. During this step, the charge transfer MOS transistor 109 and the reset MOS transistor 111 are controlled to the on state so as to transfer to the sense node 110 photogenerated charges previously accumulated in the pinned area 105 during the previous step.

More specifically, FIG. 4C illustrates a subsequent exposure step, or exposure phase. During this step, the charge transfer MOS transistor 109 and the reset MOS transistor 111 are controlled to the off state. The pinned area 105 then acts as a collection area for charges photogenerated by the photodiode 101 during the exposure step. As the potential well constituted by the metal connection element 103 has been previously filled in the step previously described in relation to FIG. 4A, the charges photogenerated during the exposure step and routed by the current IPH of the photodiode 101 are accumulated in the pinned area 105 and cause its voltage to decrease from the voltage Vp.

The quantity of charges accumulated in the pinned area 105 is proportional to the photon current IPH produced by the non-pinned photodiode 101 during the exposure step. The quantity of charges accumulated during this step is therefore proportional to an incident luminous flow to which the photodiode 101 is exposed.

More specifically, FIG. 4D illustrates a subsequent charge transfer step. During this step, the charge transfer MOS transistor 109 is controlled at the on state, and the charges accumulated in the pinned area 105 during the exposure step are then transferred to the sense node 110.

The sense node 110 is first initialized to the reset voltage VRTRST, and the value of the voltage present at the sense node 110 is read on the column conductive track Vx, and stored at the foot of the column, before implementing the charge transfer by opening the charge transfer MOS transistor 109. A second reading of the voltage present at sense node 110 is then taken after transfer, and this value is stored at the foot of the column. These two successive readings of the voltage present at sense node 110 enable Correlated Double Sampling (CDS) to be performed, thus allowing kTC noise as well as any voltage offset and/or fixed noise in the readout circuit to be eliminated.

Depending on the incident luminous flow, the voltage read at sense node 110 of pixel 100 has:
a plateau area, corresponding to conditions of low illumination (or too short exposure time) for which the potential well formed by the metallic connection element 103 cannot be filled during the preliminary step;
a linear area, corresponding to a case where the incident luminous flow is sufficient for the potential well to be completely filled during the preliminary step, the photogenerated charges being then able, during the exposure step, to be stored in the pinned area 105 and the conversion of current IPH into charge quantity being able to take place; and
a saturation area, corresponding to a case where the incident luminous flow is too great (or the exposure time too long), the pinned area 105 then being completely filled with charges until it saturates, or even overflows, onto the neighboring nodes.

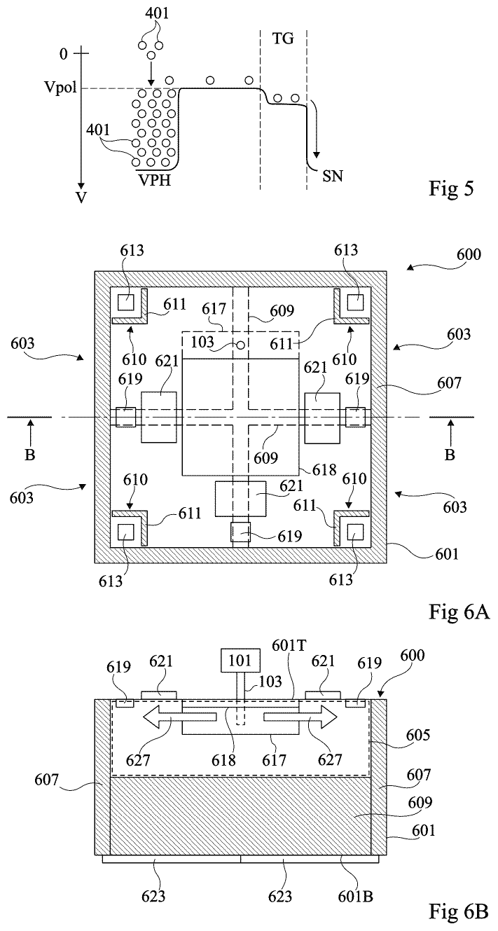

FIG. 5 is a graph illustrating an alternative operation of the pixel 100 shown in FIG. 1. More specifically, FIG. 5 illustrates operation of pixel 100 in “cascode” mode. The operating mode shown in FIG. 5 corresponds, for example, to a case where the pixel 100 is devoid of the charge transfer MOS transistor 109, or where the MOS transistor 109 is maintained in the on state.

In this operating mode, once the potential well formed by the metal connection element 103 has been filled, the charges photogenerated by the photodiode 101 are continuously discharged to the sense node 110 via the pinned area 105, the pinned area 105 acting in this case as a potential barrier. The voltage present on the metal connection element 103 then has a value Vpol that is substantially constant and approximately equal to Vp. The current leaving the pinned area 105 is then substantially equal to the photogenerated current IPH by the photodiode 101. The pinned area 105 thus fulfills a cascode function, allowing the non-pinned photodiode 101 to be voltage-biased, while transmitting the photon current IPH it generates to the sense node 110.

FIG. 6A is a schematic, partial top view of a pixel 600 of image sensor according to one embodiment. FIG. 6B is a sectional view, along plane BB shown in FIG. 6A, of the pixel 600 shown in FIG. 6A.

In the example shown, the pixel 600 is formed in and on a semiconductor substrate 601, for example a silicon wafer or wafer piece, in which photosensitive areas 603 are formed. Each photosensitive area 603 extends vertically through the thickness of the semiconductor substrate 601, from a bottom face 601B of the substrate 601 and to a depth less than the thickness of the substrate 601. In the example shown, pixel 600 includes four photosensitive areas 603. When viewed from above, each photosensitive area 603 has a substantially square periphery. In the example shown, the photosensitive areas 603 are coplanar and arranged, when viewed from above, in a generally substantially square shape. The photosensitive areas 603 are formed, for example, in a region of the substrate 601 doped with a first type of conductivity, for example N-type.

In the example shown, pixel 600 further includes a region 605 formed in semiconductor substrate 601. The region 605 is located in line with the photosensitive areas 603 (above the photosensitive areas 603, in the orientation shown in FIG. 6B). Region 605 extends vertically through the thickness of semiconductor substrate 601, from a top face 601T of substrate 601 opposite bottom face 601B. When viewed from above, region 605 has a substantially square periphery. In this example, region 605 has lateral dimensions substantially equal to those of the square formed by the four photosensitive areas 603. For example, region 605 is formed in a part of substrate 601 doped with a second conductivity type opposite to the first conductivity type, P type in this example. By way of example, region 605 has a doping level of between 1.10¹⁰ and 1.10¹⁷ at./cm³. In this example, the bottom face of region 605 is in contact with the top face of the underlying photosensitive areas 603.

Each photosensitive area 603, for example, is designed to collect photons during illumination phases of the image sensor that the pixel 600 is part of, and to convert these photons into electron-hole pairs. The photosensitive areas 603 are adapted to capture light in a first range of wavelengths. In the illustrated example, the region 605 of the pixel 600 is connected, via the metal connection element 103, to the photodiode 101 in a similar way to the pixel 100 previously described in relation to FIG. 1. The photodiode 101 is adapted, for example, to capture light in a second wavelength range, different from the first wavelength range. The photosensitive areas 603 are, for example, intended to capture 2D images, and the photodiode 101 is, for example, intended to capture depth images. By way of example, the photosensitive areas 603 of the pixel 600 are adapted to capture visible light, for example blue light, and the photodiode 101 of the pixel 600 is adapted to capture infrared radiation, for example near infrared radiation.

In the example shown, the pixel 600 further includes a peripheral isolation trench 607, for example a capacitive isolation trench, laterally delimiting the region 605 and the arrangement formed by the photosensitive areas 603. More specifically, in this example, the peripheral isolation trench 607 completely surrounds the region 605 and, when viewed from above, has a substantially square contour.

Peripheral isolation trench 607 electrically allows photosensitive areas 603 and region 605 of pixel 600 to be isolated from neighboring pixels not shown in FIGS. 6A and 6B. Peripheral isolation trench 607 is formed in substrate 601. In the orientation shown in FIG. 6B, the peripheral isolation trench 607 extends vertically through the thickness of the substrate 601 from the top face 601T of the substrate 601 to the bottom face 601B of the substrate 601.

Although not detailed in FIGS. 6A and 6B, the peripheral isolation trench 607 includes, for example, an electrically conductive region the side walls of which are coated with an electrically insulating layer. The electrically insulating layer electrically isolates the electrically conductive region of the trench 607 from the substrate 601. By way of example, the electrically conductive region of trench 607 is made of polycrystalline silicon, of a metal, such as copper, or of a metal alloy, and the electrically insulating layer of trench 607 is made of a dielectric material, such as silicon oxide. By way of example, the peripheral isolation trench 607 is a Capacitive Deep Trench Isolation (CDTI) trench.

In the example shown, the photosensitive areas 603 of the pixel 600 are separated from each other by an isolation trench 609, for example a capacitive isolation trench, e.g. of the CDTI type. In this example, the pixel 600 more precisely includes an isolation trench 609 which, when viewed from above, has a generally cross-shaped form substantially centered with respect to the pixel 600. As shown in FIG. 6B, the isolation trench 609 extends vertically through the thickness of the semiconductor substrate 601 from the bottom face 601B of the substrate 601 to the region 605, without however opening out on the side of the top face 601T of the substrate 601, the isolation trench 609 having, for example, as shown in FIG. 6B, a height substantially equal to the thickness of the photosensitive areas 603. In the example shown, each photosensitive area 603 is thus bordered laterally by the peripheral isolation trench 607 and by the isolation trench 609. By way of example, trench 609 has a similar structure to trench 607. More specifically, trench 609 may, for example, have an electrically conductive region, e.g. a metallic region, or a charged region, e.g. made of charged polycrystalline silicon, the flanks of which are coated with an electrically insulating layer. Alternatively, trench 609 is a charged isolation trench, for example of the DTI (Deep Trench Isolation) type. In this case, trench 609 has no electrically conductive region.

In the example shown in FIGS. 6A and 6B, pixel 600 further includes four vertical transfer gates 610 each comprising an isolation trench 611, for example a capacitive isolation trench. In this example, each isolation trench 611 is generally L-shaped when viewed from above. As illustrated in FIG. 6B, each isolation trench 611 extends vertically through the thickness of the semiconductor substrate 601 from the top face 601T of the substrate 601 to one of the photosensitive areas 603, and partially penetrates into the photosensitive area 603 to a depth less than that of the peripheral isolation trench 607. In other words, each isolation trench 611 is interrupted in the thickness of the substrate 601 and does not open out on the side of the bottom face 601B of the substrate 601. By way of example, each isolation trench 611 has a depth of between 3 and 18 μm.

In this example, the isolation trenches 611 are, when viewed from above, located at the four corners of the square formed by the peripheral isolation trench 607. More precisely, the isolation trenches 611 are arranged so as to delimit regions of the substrate 601 which, when viewed from above, are substantially square shaped. In the example shown in FIG. 6A, parts of the substrate 601 are interposed between the ends of the L formed by each isolation trench 611 and the facing walls of the peripheral isolation trench 607.

Each isolation trench 611, for example, has a similar structure to the peripheral isolation trench 607.

The electrically conductive region of each isolation trench 611 is, for example, electrically isolated from the electrically conductive region of the peripheral isolation trench 607. This allows, for example, the electrically conductive region of each isolation trench 611 to be biased independently of the electrically conductive region of the peripheral isolation trench 607.

In the example shown, the pixel 600 further includes charge-collecting areas 613 arranged on the side of the substrate opposite the photosensitive areas 603, i.e. on the side of the face 601T of the substrate. The charge collection areas 613 extend vertically through the thickness of the substrate 601 from its top face 601T, to a depth less than that of the isolation trenches 611. In this example, each load collection area 613 is surrounded by one of the isolation trenches 611 and by the peripheral isolation trench 607. By way of example, each load collection area 613 is substantially square shaped when viewed from above. Each charge collection area 613 is, for example, more heavily doped with the first type of conductivity, in this example the N type (N⁺), than the photosensitive areas 603. By way of example, the substrate 601 has a doping level of between 1.10¹⁶ and 5.10²⁰ at./cm³ at the place where each charge collection area 613 is formed.

In the example shown, each photosensitive area 603 includes a doped region 615 of the second conductivity type, P-type in this example. The regions 615 are, for example, heavily doped with P-type (P⁺). In this example, the regions 615 extend vertically through the thickness of the substrate 601 from a face of the photosensitive areas 603 on the side of the region 605 to a depth less than the thickness of the photosensitive areas 603. Within each photosensitive area 603, region 615 forms a photodiode with a part of substrate 601 doped with the first conductivity type, N-type in this example. The region 615 further allows charge transfers from the photosensitive areas 603 to the region 605 of the pixel 601 to be blocked. Alternatively, region 615 can be omitted, for example in a case where the vertical transfer gate 610 is close to the isolation trench 609.

In the example shown, region 605 includes a doped region 617 of the first conductivity type, N-type in this example, overlaid by a heavily doped region 618 of the second conductivity type, P-type in this example. In this example, region 618 extends vertically through the thickness of substrate 601 from its top face 601T to a depth less than the thickness of region 605. In the example shown in FIG. 6A, region 618 is substantially square shaped and generally centered with respect to the peripheral isolation trench 607 of pixel 600. Furthermore, in this example, region 617 extends vertically through the thickness of substrate 601 from region 618 to a depth less than the thickness of region 605. Region 617, for example, has larger lateral dimensions than region 618, with the metal connection element 103 in contact with a part of region 617 not located in line with region 618. Regions 617 and 618 are for example analogous to regions 203 and 205 previously described in relation to FIG. 2, the region 617 of pixel 600 in FIG. 6 corresponding for example to a pinned area formed in substrate 601.

In the example shown, pixel 600 further includes charge-collecting areas 619 arranged on the side of the top face 601T of substrate 601. The charge collection areas 619 extend vertically through the thickness of the substrate 601 from its top face 601T to a depth less than the thickness of the region 617. More specifically, in this example, pixel 600 has three charge-collection areas 619, each located between one side of region 617 and one side of peripheral isolation trench 607.

In the example shown, pixel 600 further includes transfer gates 621, for example planar transfer gates, located on and in contact with the top face 601T of substrate 601. Each transfer gate 621 is located, for example, in line with a part of the substrate 601 between the region 617 and one of the charge collection areas 619. Alternatively, pixel 600 could include different numbers of transfer gates 621 and charge collection areas 619 from those shown, for example four charge collection areas 619 associated respectively with four transfer gates 621.

In this example, the photosensitive areas 603 and the photodiode 101 (not detailed in FIGS. 6A and 6B) are intended to be illuminated from the bottom face 601B of the substrate 601. As shown in FIG. 6B, pixel 600 may further include color filters 623 located on and in contact with the bottom face 601B of substrate 601. In the example shown, each color filter 623 is located in line with one of the photosensitive areas 603. Some color filters 623 are, for example, transparent to only part of the visible spectrum, e.g. blue light, and to at least part of the infrared spectrum, e.g. near infrared radiation, while other color filters 623 are, for example, transparent to another part of the visible spectrum, e.g. green or red light, and opaque to infrared radiation. To this end, a layer of resin (not shown in FIGS. 6A and 6B) is provided, for example, in line with the color filters 623 that are transparent to green or red light. Although not shown in FIGS. 6A and 6B, pixel 600 may further include one or more passivation layers, for example interposed between the bottom face 601B of substrate 601 and color filters 623, and other optical elements such as one or more micro-lenses.

During a pixel 600 exposure phase, for example, electron-hole pairs are created within each photosensitive area 603. During this phase, the electrically conductive region of each isolation trench 611 is brought to a fixed potential, for example a negative potential, e.g. equal to about −1.5 V, by a control circuit (not shown). During the sensor exposure phase, the application of this potential to the electrically conductive region of each trench 611 enables a potential barrier to be formed in a transfer region located inside each vertical transfer gate 610, between the photosensitive area 603 and the collection area 613. In the example shown, the transfer region is bordered by the inner side walls of the peripheral isolation trench 607 and isolation trench 611, and extends vertically, through the thickness of the substrate 601, beneath the collection area 613.

The presence of the potential barrier in the transfer region allows, during the exposure phase, a transfer of photogenerated electrons from the photosensitive area 603 to the collection area 613 to be blocked. This potential barrier results from the presence, along the side walls of the isolation trenches 607 and 611, of a hole-attracting inversion layer, in this example.

During a read phase subsequent to the exposure phase, the electrically conductive region of each isolation trench 611 is initialized, for example, in the case of a sampling channel, or maintained, in the case of a photodiode reset channel, at a potential higher than the potential applied during the exposure phase, for example a positive potential, e.g. equal to around 0.5 V, by the control circuit (not shown). Applying this potential to the electrically conductive region of each trench 611 lowers, or even eliminates, the potential barrier in the transfer region between the photosensitive areas 603 and the charge collection areas 613. The disappearance of the potential barrier enables photogenerated electrons to be transferred 625 from the photosensitive areas 603 to the collection areas 613 during the read phase. By way of example, the charge collection areas 613 are each brought to a fixed potential, for example a positive potential, e.g. equal to around 2.5 V, during the exposure and read phases. This allows photogenerated electrons to be attracted towards the areas 613 during the read phase.

Further, during a phase of exposing the pixel 600, charges are for example accumulated inside the region 605 as previously explained in relation to FIGS. 4A to 4B for the pinned area 105 of the pixel 100. For example, during this phase, the charges in region 605 are transferred, in turn, to the various charge collection areas 619 of pixel 600. To do this, one of the planar transfer gates 621 is, for example, brought to a first potential to transfer charges from region 605 to one of the areas 619, while the other gates 621 are brought to a second potential to block electron transfer to the other areas 619. Then, another gate 621 is brought to the first potential, the other gates then being brought to the second potential, and so on until all gates 621 have been successively brought to the first potential. During the same exposure phase, the gates 621 of pixel 600 are thus opened sequentially, for example by applying control signals that are out of phase with one another to these gates, in order to enable charge transfer from region 605 to a single collection area 619 at a time. This sequence of opening the transfer gates 621 is repeated many times during the exposure phase, for example. This enables pixel 600 to implement time-of-flight distance measurements, for example, indirect time-of-flight (iToF) measurements. By way of example, the opening frequency of each transfer gate 621 is between 10 and 300 MHz, and each exposure phase includes a number of opening periods of the transfer gates 621 between ten thousand and one million.

During the exposure phase, the gates 621 brought to the second potential force a potential barrier within a transfer region located between the region 617 of the region 605 and the collection areas 619 associated with these gates. This potential barrier results from the presence of a hole-attracting inversion layer under the planar transfer gates 621 brought at the second potential, in this example. Conversely, the gate 621 being brought to the first potential lowers, or even eliminates, the potential barrier within the transfer region between the region 617 and the charge collection area 619 associated with this gate. By way of example, the first potential is positive, e.g. equal to approximately 0.5 V, and the second potential is lower than the first potential, e.g. negative, e.g. equal to approximately-2 V.

By way of example, the charge collection areas 619 are each brought to a fixed starting potential, for example a positive potential, e.g. equal to around 2.5 V, prior to the exposure phase. This allows the photogenerated charges to be attracted towards areas 619 during the exposure phase. During the exposure phase, the potential of each area 619 decreases according to a number of electrons transferred from region 605 to that area 619. At the end of the exposure phase, the potential of areas 619 is measured, for example, to determine the total amount of charges that were integrated by each area 619 during the exposure phase. Once the measurement is complete, the charge collection areas are brought back to their initial potential, for example, before the next exposure phase.

In the example shown, where the pixel 600 includes three planar transfer gates 621 respectively associated with three charge collection areas 619, one of the planar transfer gates 621, for example, implements a reset function, the pinned area being emptied, or reset, permanently by maintaining this transfer gate 621 in the on state during phases where no sample is acquired by the pixel 600.

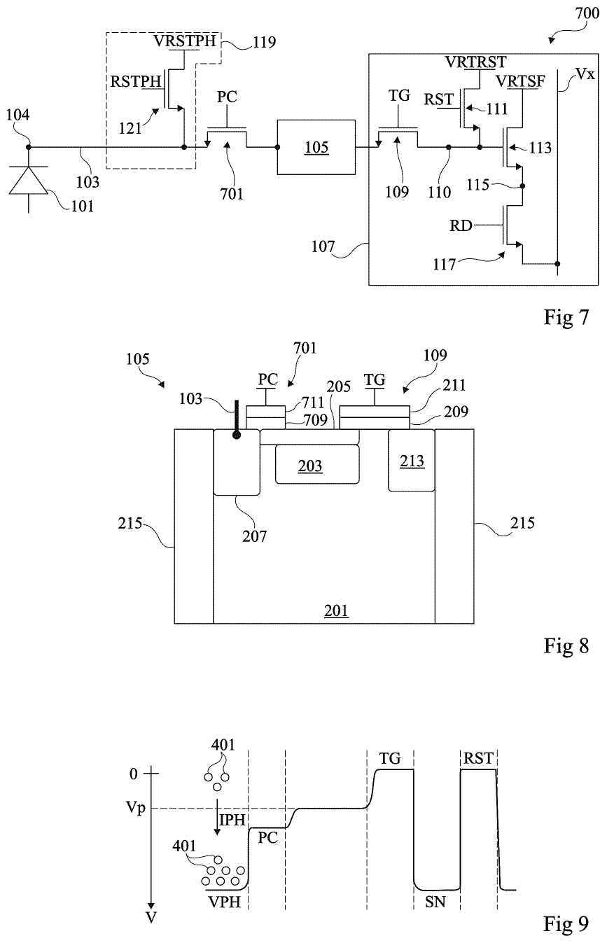

FIG. 7 illustrates, schematically and partly, an example of an image sensor pixel 700 according to one embodiment. The pixel 700 shown in FIG. 7 comprises elements in common with the pixel 100 shown in FIG. 1. These common elements will not be described again below.

The pixel 700 shown in FIG. 7 differs from the pixel 100 shown in FIG. 1 in that the pixel 700 additionally comprises another transistor 701, for example a MOS transistor, connected between the metal connection element 103 and the pinned region 105. In the example shown, the transistor 701 comprises a conduction terminal, e.g. the source, connected to the metal connection element 103, another conduction terminal, e.g. the drain, connected to the pinned region 105, and a control terminal, or gate, connected to a node for applying a control voltage PC. In the case that pixel 700 comprises optional circuit 119 including reset MOS transistor 121, the source of transistor 121 is connected, for example, to the source of transistor 701.

The transistor 701 is designed, for example, to compensate for the fact that the electric field lines between the metal connection element 103 and the pinned area 105 are highly dependent on the geometry of the structure and doping levels of the pixel 700. Transistor 701, for example, is controlled to be at the on state to ensure the passage of photogenerated charges 401 from metal connection element 103 to pinned area 105. By way of example, the channel voltage level of transistor 701 is adjusted by its gate voltage PC. This advantageously allows external control over the slope of the potential levels between the metallic connection element 103 and the pinned area 105 to be provided. In particular, this allows the steepest possible slope to be reached in the case of small structures with low charge collection areas.

FIG. 8 is a schematic, partial side and sectional view of an example of the pinned area 105 of the pixel 700 shown in FIG. 7, according to one embodiment.

The pinned area 105 of pixel 700 shown in FIG. 8 differs from the pinned area 105 of pixel 100 shown in FIG. 2 in that pinned area 105 of pixel 700 includes transistor 701 comprising a gate region including an electrically insulating layer 709 interposed between an electrically conductive layer 711, acting for example as gate electrode of MOS transistor 701, and the top surface of substrate 201. The layers 709 and 711 of transistor 701 are, for example, analogous or identical to the layers 209 and 211, respectively, of transistor 109. In the illustrated example, the gate region extends laterally over regions 203 and 205, region 203 constituting, for example, a drain region of MOS transistor 701, and over region 207, region 207 forming, for example, a source region of MOS transistor 701. In the example shown, region 203 is separated laterally from region 207 by a part of substrate 201.

FIG. 9 is a graph illustrating an operating step of the pixel 700 shown in FIG. 7 according to one embodiment.

The operating steps of pixel 700 are, for example, analogous to those of pixel 100 and can be deduced, by those skilled in the art, from the above description in relation to FIGS. 4A to 4D in particular. Specifically, the step illustrated in FIG. 9 is, for example, analogous to the operating step of pixel 100 previously described in relation to FIG. 4A.

More precisely, FIG. 9 illustrates a preliminary step in which photogenerated charges 401, here electrons, are accumulated at node 104 under the effect of a current IPH produced by photodiode 101 until the voltage VPH present at node 104 becomes substantially equal to the pinched-off voltage Vp of pinned area 105. During this step, the MOS transistor 701 is maintained in the on state, the control voltage PC applied to its gate being, in the example shown, greater than the pinched-off voltage Vp.

One advantage of pixels 100, 600, and 700 is that they enable the use of a non-pinned photodiode associated with a 4T-type readout circuit. This allows, for example, image sensors to be implemented with photodiodes that cannot be implemented with a pinned structure, such as silicon-hybridized photodiodes, while keeping a charge-integration mode of operation. This allows kTC noise to be reduced compared with an image sensor comprising non-pinned photosites or photodiodes associated with a 3T-type circuit.

Various embodiments and variants have been described. Those skilled in the art will understand that certain features of these embodiments can be combined and other variants will readily occur to those skilled in the art. In particular, those skilled in the art will be able to adapt the reading circuit 107 from the pixel 100 shown in FIG. 1 to the pixel 600 shown in FIGS. 6A and 6B from the indications of the present description. Furthermore, those skilled in the art will be able to combine the design of the pixel 700 with that of the pixel 600, i.e. to provide, in the pixel 600, a transistor connected between the metal connection element 103 and the pinned region 617.

Finally, the practical implementation of the embodiments and variants described herein is within the capabilities of those skilled in the art based on the functional description provided hereinabove. In particular, the embodiments described are not limited to the particular examples of materials and dimensions mentioned in the present description.

1. An image sensor comprising a plurality of pixels, each pixel including a non-pinned photodiode connected, by a metal connecting element, to a pinned area formed in a first semiconductor substrate.

2. The sensor according to claim 1, wherein the non-pinned photodiode comprises a P-type doped anode semiconductor region and an N-type doped cathode semiconductor region.

3. The sensor according to claim 2, wherein the anode and cathode semiconductor regions of the non-pinned photodiode are joined.

4. The sensor according to claim 1, wherein the non-pinned photodiode is formed on a second semiconductor substrate different from the first substrate.

5. The sensor according to claim 4, wherein the non-pinned photodiode is hybridized to the first substrate, the first substrate being made of silicon.

6. The sensor according to claim 4, wherein the metallic connection element comprises conductive tracks, conductive vias and/or contact pick-up elements formed in first and second interconnection stacks located on the first and second substrates respectively.

7. The sensor according to claim 1, wherein the pinned area comprises a first N-type doped semiconductor region formed in the first substrate, the first substrate being P-type doped.

8. The sensor according to claim 7, wherein a second P-type doped semiconductor region formed in the first substrate is interposed between a top face of the first substrate and the first semiconductor region.

9. The sensor according to claim 8, wherein the second semiconductor region has a higher doping level than the first substrate.

10. The sensor according to claim 7, wherein the metal connection element is in contact with a third, N-type doped semiconductor region extending vertically through the thickness of the first substrate from its top face.

11. The sensor according to claim 10, wherein the first semiconductor region penetrates into the third semiconductor region.

12. The sensor according to claim 1, wherein each pixel further includes a transistor connected between the metal connection element and the pinned area.

13. The sensor according to claim 1, wherein the pixel further comprises:
at least one first photosensitive area formed in the first substrate and adapted to collect light in a first range of wavelengths;
a fourth semiconductor region formed in the first substrate in line with said at least one photosensitive area, wherein the pinned area is formed;
at least one charge collection area disposed on the opposite side of the second substrate to said at least one first photosensitive area;
at least one transfer region extending from said at least one first photosensitive area to said at least one charge collection area; and
at least one transfer gate extending vertically between said at least one transfer region and the fourth semiconductor region and laterally bordering said at least one transfer region.

14. The sensor according to claim 13, wherein the non-pinned photodiode is adapted to capture light in a second wavelength range, different from the first wavelength range.

15. The sensor according to claim 13, wherein the pixel further includes at least one another transfer gate extending laterally on said side of the first substrate opposite said at least one first photosensitive area and at least one another charge collection area.

16. The sensor according to claim 1, wherein the pinned area is not intended to be subjected to incident light radiation.
